(19) United States
(12) Patent Application Publication
(10) Pub. No.: US 2012/0228755 A1
(43) Pub. Date: Sep. 13, 2012

(54) SEMICONDUCTOR MODULE AND MANUFACTURING METHOD THEREOF

(75) Inventors: Toshihiko NAGANO, Kanagawa-ken (JP); Hiroshi Yamada, Kanagawa-ken (JP); Kazuhide Abe, Kanagawa-ken (JP); Kazuhiko Itaya, Kanagawa-ken (JP); Taihei Nakada, Kanagawa-ken (JP)

(73) Assignee: KABUSHIKI KAISHA TOSHIBA, Tokyo (JP)

(21) Appl. No.: 13/235,386

(22) Filed: Sep. 18, 2011

(30) Foreign Application Priority Data
Mar. 8, 2011 (JP) 2011-050842

(51) Int. Cl. H01L 23/053; H01L 21/56

(52) U.S. Cl. 257/698; 438/126; 257/E23.188; 257/E21.502

(57) ABSTRACT

A semiconductor module includes a high frequency chip, an insulating cap, a through electrode, interconnections, and an insulating layer. The insulating cap forms a hollow with the chip to cover the chip. The through electrode passes through a first plane of the cap and a second plane of the cap, the first plane facing the chip, the second plane being on a side opposite to the first plane. The interconnections are provided on the cap and connected to the through electrode. The insulating layer is provided on the cap and fills a portion between the interconnections therewith.

### CROSS REFERENCE TO RELATED APPLICATION

This application is based upon and claims the benefit of priority from the prior Japanese Patent Application No. 2011-050842, filed on Mar. 8, 2011, the entire contents of which are incorporated herein by reference.

### FIELD

An embodiment relates basically to a semiconductor module and a manufacturing method thereof.

### BACKGROUND

Previously, a high-frequency element handles a high-frequency signal (hundreds of MHz to GHz) of high intensity (several W at maximum) to need impedance matching or loss reduction, thereby making it difficult to enable packaging or module integration of high-frequency elements. A high-frequency element is often used as a module including a discrete high-frequency signal processing chip mounted on a mounting board together with passive parts and other elements. The discrete high-frequency signal processing chip is sealed in a package made of metals, ceramics, and metal-ceramic composites before being mounted on the mounting board. For example, a high frequency chip called MMIC (Monolithic Microwave Integrated Circuit) needs to perform impedance matching at an input/output part thereof and also to enable a low power loss. For this purpose, MMIC is die-bonded to a package using materials such as Au, Au—Sn, etc. After the die-bonding, MMIC is wire-bonded with a gold wire and sealed with hermetic sealing to be completed. A high-frequency module is entirely completed by mounting MMIC and the other parts on a mounting board with a capacitor, an inductor, and a resistor, etc. to be wired using solder, wire bonding, etc. Various methods of the packaging or the mounting are selected in accordance with the use conditions of the high-frequency element handling a wide range of frequencies and power.

In recent years, SOC (System on Chip) and SIP (System in Package) are proposed as a high density packaging technique of electron devices. As a result, a miniaturization, high integration, multi-function, and low cost technologies are extensively developed. In the technologies, two or more semiconductor chips having different functions are included in a package or a module.

### BRIEF DESCRIPTION OF DRAWINGS

Aspects of this disclosure will become apparent upon reading the following detailed description and upon reference to accompanying drawings.

FIG. 1 is a sectional view showing a manufacturing process flow of a semiconductor module.

FIG. 2 is a view showing a resin wafer, each semiconductor module, and a sectional view of the module.

FIG. 3 is a sectional view showing another manufacturing process flow of the semiconductor module.

FIG. 4 is an enlarged view showing a section of the semiconductor module.

FIG. 5 is a perspective view showing the semiconductor module.

FIGS. 6A and 6B are schematic views showing a conventional semiconductor module and a semiconductor module of an example 1, respectively.

FIGS. 7A and 7B are graphs showing resistivity dependence of a power loss.

FIG. 8 is a graph showing resin-thickness dependence of an interconnection width and a power loss.

FIG. 9A is a graph showing changes in the power losses with hollow heights.

FIG. 9B is a view to partially enlarge a cross section of a semiconductor module.

FIG. 10 is a graph showing power losses for the resin layers having various dielectric constants.

FIG. 11 is a graph showing thickness dependence of the power losses.

FIGS. 12A to 12D are plan views and top views showing forms of input/output interconnections.

FIG. 13 is a perspective view showing an example of the input/output interconnections formed with passive parts embedded.

### DESCRIPTION

As will be described below, according to an embodiment, a semiconductor module includes a high frequency chip, an insulating cap, a through electrode, interconnections, and an insulating layer. The insulating cap forms a hollow with the chip to cover the chip. The through electrode passes through a first plane of the cap and a second plane of the cap, the first plane facing the chip, the second plane being on a side opposite to the first plane. The interconnections are provided on the cap and connected to the through electrode. The insulating layer is provided on the cap and fills a portion between the interconnections therewith.

### EMBODIMENT

An embodiment will be described with reference to drawings. The drawings are conceptual. Therefore, a relationship between a thickness and a width of each portion and a proportionality factor among the respective portions are not necessarily the same as an actual thing. Even when the same portions are drawn, their sizes or proportionality factors may be drawn differently from each other with respect to the drawings.

Wherever possible, the same reference numerals or marks will be used to denote the same or like portions throughout figures. The same description will not be repeated.

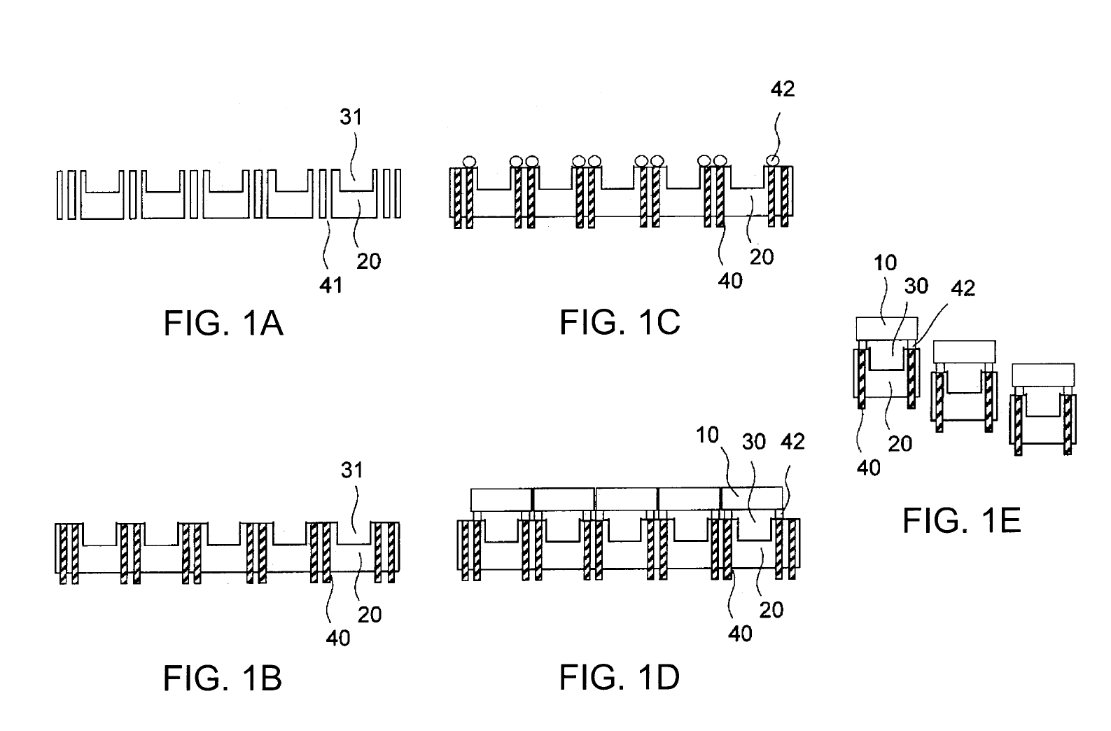

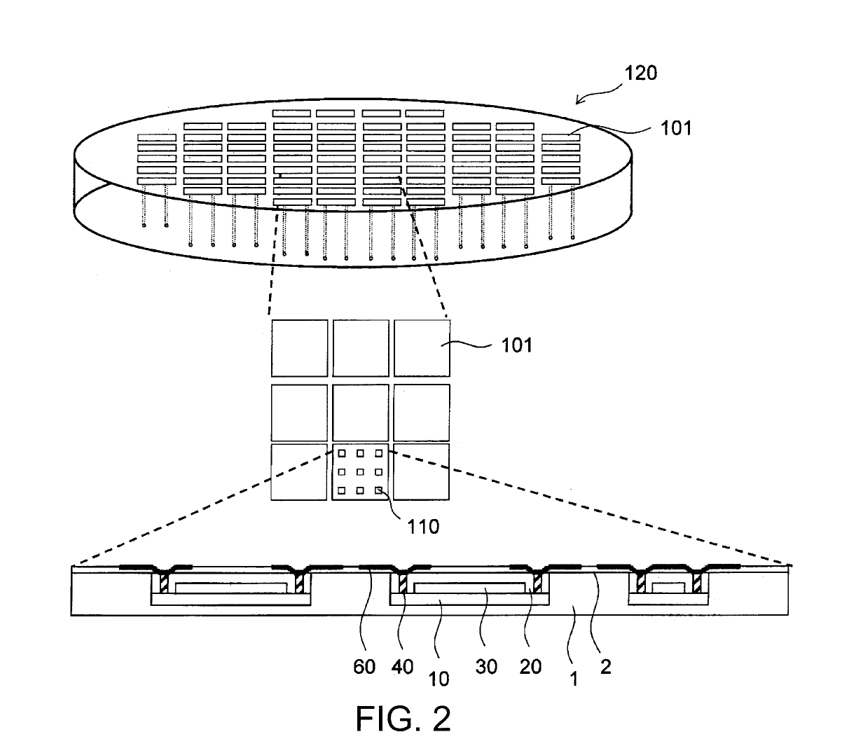

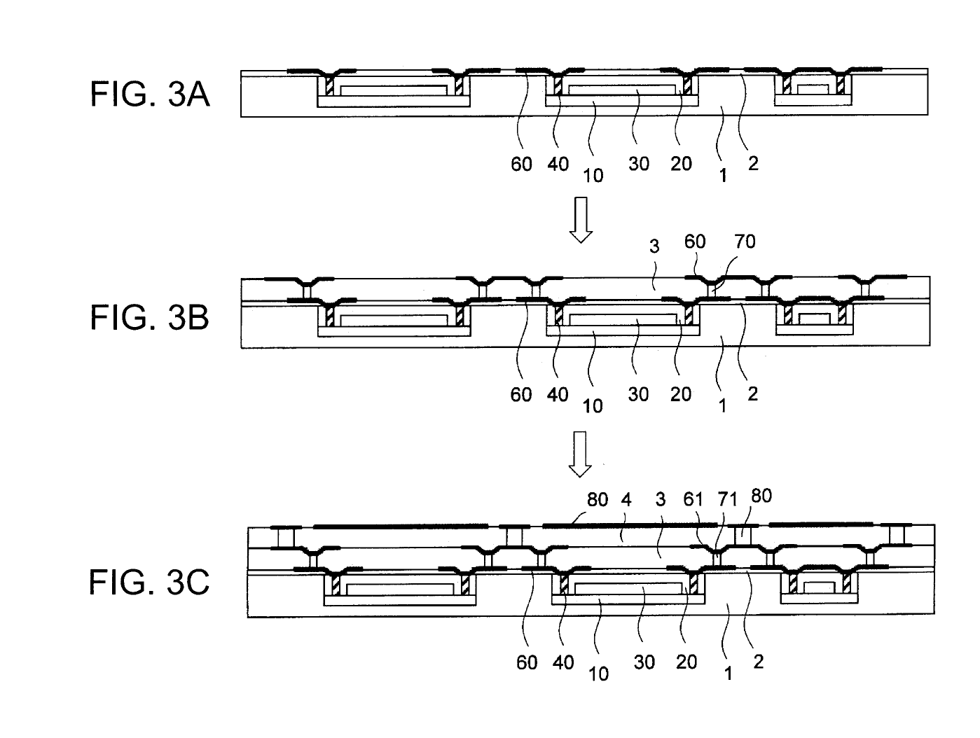

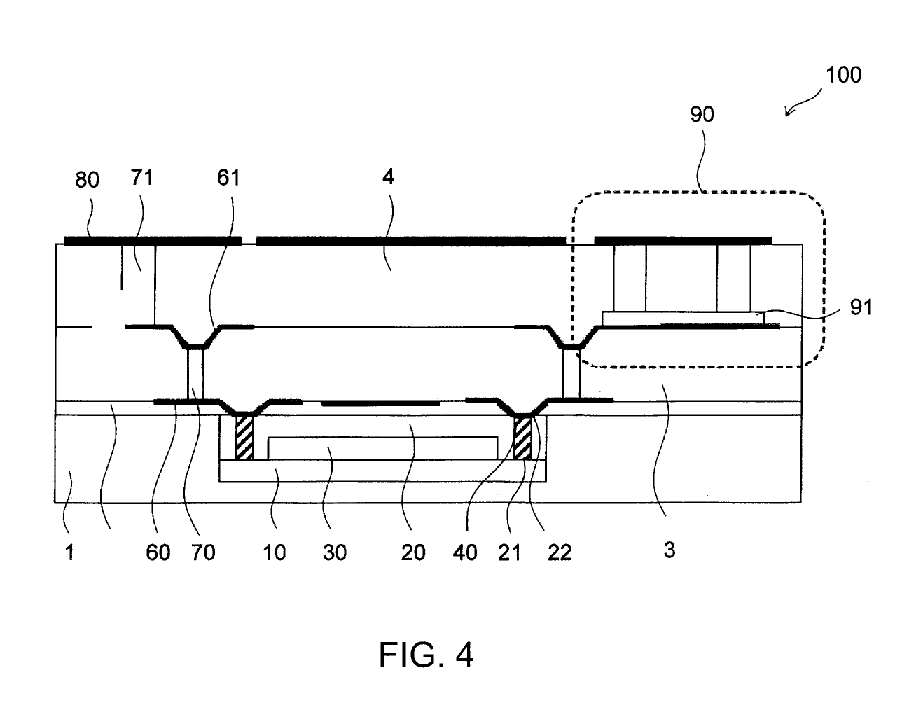

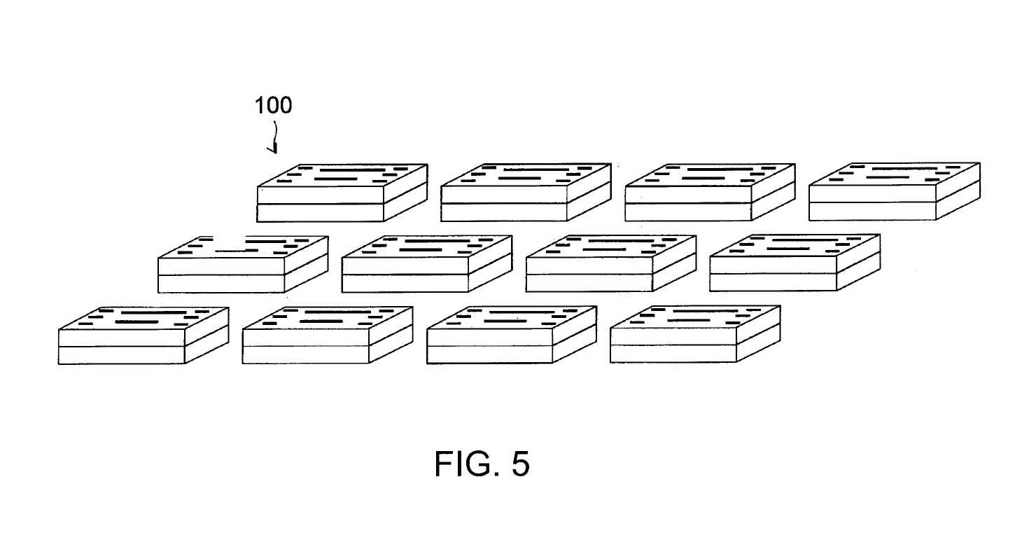

FIG. 1 is a sectional view showing a manufacturing process flow of a semiconductor module. FIG. 2 is a view showing a resin wafer, each semiconductor module, and a sectional view of the module. FIG. 3 is a sectional view showing another manufacturing process flow of the semiconductor module. FIG. 4 is an enlarged view showing a section of the semiconductor module. FIG. 5 is a perspective view showing the semiconductor module. A configuration of the semiconductor module will be described with reference to FIGS. 4 and 5.

A semiconductor module 100 is provided with a high frequency chip 10, an insulating cap 20, a first plane 21, a through electrode 40, input/output interconnections 70, a third resin (insulator layer) 3. The cap 20 covers the high frequency chip 10 having a hollow 30 with the high frequency chip 10. The first plane 21 faces the high frequency chip 10. The through electrode 40 is disposed in the cap 20 and passes through the first plane 21 and a second plane 22 on the opposite side of the first surface. The input/output interconnections 70 are connected to the through electrode 40. A space between the input/output interconnections 70 is filled with the third resin 3.

The high-frequency chip 10 and the cap 20 are embedded in a first resin 1. Moreover, the first resin 1 and the cap 20 are covered with a second resin 2. The through electrode 40 is provided with an opening thereon and a electrode pad is formed on the opening. The third resin 3 is formed on the second resin 2. An opening is formed in a portion of the third resin 3, and the input/output interconnection 70 is formed in the opening. The input/output interconnection 70 is connected to an electrode pad 60. A fourth resin 4 (an insulator layer) is formed on both the third resin 3 and the electrode pad 60. An input/output interconnection 71 is formed on an opening which is formed in the fourth resin 4. The input/output interconnection 71 is connected to the electrode pad 60. A lead pad 80 is formed on the input/output interconnection 71.

Although the two input/output interconnection layers 70, 71 and two resin layers (the third resin 3, fourth resin 4) are formed in the embodiment, a single layer may serve as the input/output interconnection layers and the resin layers.

The dielectric film 91 is formed on a portion of the electrode pad 60. The upper input/output interconnection 71, the lead pad 80, and the dielectric film 91 form an MIM capacitor. The lead pad 80 is formed on the upper input/output interconnection 71. The electrode pad 61 and the dielectric film 91 are formed under the input/output interconnection 71.

The high-frequency chip 10 is a MMIC chip based on GaAs, of which frequency is 500 MHz or more, and serves as a switch to switch a channel of high frequency signals. The MMIC chip is packaged by the silicon cap 20 having a high resistance of 100 Ωcm or more, for example.

The miniaturization of the package is enabled by the cap 20 and the through electrode 40 instead of the miniaturization of the previous ceramic package. The cap 20 can be made of a glass substrate, a high-resistance silicon substrate, etc. It is effective to make the area of the cap 20 in contact with the surface of the high frequency chip 10 as small as possible for the miniaturization of the package. The small area of the cap 20 effectively limits a high-frequency signal loss due to an eddy current. Therefore, it is effective to employ a hollow cap.

A manufacturing method of the semiconductor module 100 will be described below.

First, a packaging process is described. The packaging process includes performing D-RIE (Deep Reactive Ion Etching) to a high-resistance silicon wafer to form a hollow portion 30 and the through electrode 40 therein. The through electrode 40 can be formed employing the silicon wafer as a starting material. The silicon wafer is deeply etched using DRIE and a metal layer is subsequently formed on the etched silicon wafer by sputtering, CVD, and plating, etc. When the insulating glass wafer is employed as the start material for the cap 20, the insulating glass wafer may be deeply etched using DRIE or machining as well as the silicon wafer. Both DRIE and the machining enable it to form a deep hole having a depth of about 100 μm.

A silicon wafer will be used throughout the embodiment. As shown in FIG. 1A, the silicon wafer has a trench 31 for the hollow portion 30 and a through hole 41 for the through electrode 40, both being formed with D-RIE. DRIE is conducted by a Bosch process, i.e., passing an SF₆ gas and a C₄F₈ gas alternately through a mass flow controller to a process chamber in order to apply plasma processing to the silicon wafer. Before performing DRIE, resist is beforehand patterned. A high-resistance silicon wafer is employed, which has a resistivity of 1000 Ωcm and a thickness of 10 μm. The trench for the hollow portion measures 50 μm height (etched depth). The through hole for the through electrode measures 100 μm height, i.e., the same as the thickness of the silicon wafer. After etching, the resist and the fluoride passivation film are removed from the silicon wafer and a 1-μm thick thermally-oxidized film is further formed entirely on the silicon wafer with a vapor oxidation film in order to improve the insulation quality thereof.

Next, as shown in FIG. 1B, the through electrode 40 is formed by Cu-electrolytic plating. It is necessary to provide a specific portion of the silicon wafer with a metal layer, i.e., a plating layer (seed layer). A 1 μm-thick Cu layer is sputtered entirely on the silicon wafer including the front and back sides thereof in order to subsequently form the plating film. A 100 μm-thick Cu film is further formed on the entire silicon wafer, of which unnecessary portion of the Cu film is removed from the silicon wafer by grinding, lithography, and etching to leave pads. Alternatively, a Cu or Ni electrolessly-plated layer may be laminated on the Cu sputtered film to improve the plate adhesion or the shape control of the electrolytically-plated Cu thick layer. This prevents the electrolytically plated layer from closing the opening of the through electrode 40. A problem of closing the opening may cause insufficient plating inside the entire hole of the through electrode 40. When using electroless plating, the problem of closing the opening is eliminated, thereby allowing it to form the through electrode 40 which is filled with a plated Cu layer.

The above-mentioned process can be applied to a glass substrate excepting steps of RIE and thermal oxidation. Any steps other than RIE and the thermal oxidation can be applied in the above-mentioned process.

As shown in FIG. 1C, before forming bump electrodes 42, a 1 μm-thick Ni layer is plated on Cu pads of the caps 20 to prevent the surface oxidation of the Cu pads. A 0.2 μm-thick Au layer is further formed on the Ni plated layer by flash plating.

Subsequently, the bumps 42 made of Sn—Ag low temperature solder are formed on the Cu pads. The formation of the bumps 42 is followed by a reflow process using a reflow furnace.

After that, as shown in FIG. 1D, the whole substrate is bonded to the MMIC chip by a flip-chip bonder at temperatures of 100° C. to 200° C. In addition to bonding by Sn—Ag low temperature solder, bonding by eutectic-alloy solder of Au/Au—Sn, bonding by Au/Ag—Sn—Cu solder, Au—Au direct bonding, bonding by conductive polymer, and anodic bonding between Si and Sio₂, etc. are employed.

The above-mentioned process can be employed also for the glass caps.

As shown in FIG. 1E, a 3-inch silicon wafer is diced to make prescribed-size pieces (package-sized pieces) thereof with a diamond blade in a dicing apparatus. Examples of the dicing include laser dicing and ultrasonic dicing, both being capable of providing the pieces (MMIC chips).

The above-mentioned process can be employed for the glass substrate.

A process for expanding to a large-sized wafer will be described below. The package-sized pieces are sealed in a resin using a vacuum printing method, thereby reforming the package-sized pieces collectively in a wafer form. The wafer form can be fabricated by a process technology or equipment in a semiconductor preceding process.

The packaged MMIC chips are reassembled in a first resin 1 together with other kinds of chips, thereby forming a resin wafer 120 having a diameter of 3 inches to 6 inches. As shown in FIG. 2, the resin wafer 120 has two or more modules 101, and each module 101 includes two or more packages 110. The vamp electrode 42 is not shown in FIG. 2. Examples of the first resin 1 include epoxy resin, polyimide resin, and fluorine system resin, all of which have a low dielectric constant. Packages 100 undergo alignment to be embedded in the resin 1 and a second resin 2 is applied onto the packages 100 in order to prevent short-circuit. The resin wafer 120 is sintered at temperatures of 100° C. to 200° C. The resin wafer 120 is grinded or polished with a grinder or a CMP system so that the thickness of the resin wafer 120 is suitable for a process after the grinding or the polishing. Moreover, an epoxy residue or a residue coming from the adhesive substrate for the aligning and embedding is removed by washing with acetone and so on. After that, lithography is applied to the second resin 2 to pattern holes 70 for the input/output interconnections on the pads of the cap 20. The holes 70 are filled with a metal. The electrode pad 61 is formed in the holes filled with the metal to be in contact with the through electrode 40. Thus, the reconstructing process of the resin wafer 120 is completed.

According to the process described above, a semiconductor routine process enables it to complete a semiconductor module without particular equipment or a mounting process different from a routine one. The above process can be conducted using the process technologies described above independently of the material of the cap 20.

Forming input/output interconnections will be described below.

As shown in FIGS. 3A to 3C, the input/output interconnections 70 are formed on the reconstructed resin wafer 120. The input/output interconnections 70 are important to perform impedance matching in a high frequency circuit. In order to match the impedance of the input/output interconnections 70, the following parameters are to be optimized, which include the dielectric constant and thickness of the insulating layer 3 between the input/output interconnections 70. The parameters also include the thickness and width of the input/output interconnections 70. After optimizing these parameters, masks and circuits are designed.

As shown in FIGS. 3A and 3B, the third resin 3 is applied to the side of the electrode pads 60 on the resin wafer 120 and is patterned with lithography, thereby opening holes for input/output interconnections 70. A highly insulating residue or an organic residue adheres on the inner surface of the holes to cause a reduction of deposit efficiency of the film to be formed in the next step or to cause a high contact resistance. In order to prevent the reduction or the high contact resistance, surface modification by short-time etching or acidizing is given using a fluorine-based dry etching system.

The input/output interconnections 70 are formed on the modified inner surface by sputtering, etc. A several μm-thick metal film of Cu, Au and so on is routinely formed on a Ti adhesion layer in order to reduce interconnection resistance. After the film formation, the metal films are lithographically etched to be patterned as a prescribed form for the input/output interconnections 70.

As shown in FIG. 3C, when forming a multilayer of input/output interconnections and a resin layer, the electrode pads 60 are firstly formed on the lower input/output interconnections 70. Subsequently, a fourth resin layer 4 and upper input/output interconnections 71 are secondly formed on the electrode pads 60 in the same way. Several μm-thick lead pads 80 to double as mounting pads are finally sputtered or plated on the upper input/output interconnections 71 to be patterned in the same semiconductor process.

Furthermore, the process for the upper and lower input/output interconnections 70, 71 can provide the embedding of passive parts. The passive parts were previously mounted on a printed board in a form of discrete chip such as a capacitor, an inductor, a resistor, a filter and so on with solder bumps as well as other elements. This mounting was to control the quality of electric properties. There were several problems in the previous mounting. The problems include the followings:

the number of mounted parts increases;
expensive equipment including a flip-chip bonder is needed for position-accurate mounting; and
a interconnection length increases so that values of resistance, capacitance, and inductance affect impedance matching to decrease a design margin.
In order to solve the problems, the input/output interconnections 70 and 71 are used to effectively introduce embedded passive parts.

A capacitor, an inductor (coil), and a resistor can be actually formed using the input/output interconnections 70 and 71 which are on the third resin 3, on the fourth resin 4, or between the third resin and the fourth resin 4. For example, as shown in FIG. 4, an insulating resin film is formed as a dielectric film 91 of a capacitor on the electrode pads being on the third resin 3. The insulating resin film is sandwiched between the electrode pad 61 connected to the lower input/output interconnection 70 and the lead pad 80 connected to the upper input/output interconnection 71, thereby providing an MIM capacitor (Metal-Insulation-Metal). Thus, passive parts can be formed in a routine semiconductor process. In addition, the capacitor is embedded in the third resin 3 and in the fourth resin 4 to enable the small mounting area and the short interconnection thereof. The small mounting area and the short interconnection result in a capacitor with a high Q value and a low loss due to the short interconnection. A spiral inductor can be formed by routing the input/output interconnections 70, 71 and by partially leveraging the through electrode 40, thereby providing the spiral inductor with a high Q value. The resistor can be formed by patterning, e.g., a Ni—Cr sputtered film or a Ni—Cr—Al—Si sputtered film.

A laser trimming technique can provide the above-mentioned passive parts with higher accuracy for reduced variations in properties from element to element as well as the mounting of the discrete passive parts. The above-mentioned techniques enable it to greatly reduce the number of mounted parts and to ensure electric quality control of the mounted parts as well as chip parts.

After forming the input/output interconnections 70 and 71, the passive parts are evaluated, as are formed on the wafer, for input/output impedance and a power loss (power loss) using an impedance analyzer. The passive parts are evaluated as are formed in a form of the wafer, thereby allowing it to inspect all the passive parts on the wafer. This 100% evaluation has a great effect on the quality control. In spite of the lead pads 80 on the surface of the module, the module has the third and fourth resin layer 3, 4 which is transparent. Therefore, the module is entirely transparent to allow it to check the alignment, its accuracy, and the formation of interconnections from the outside as needed. The transparency also allows it to easily check troubleshooting.

Finally, a 3-inch wafer to be selected is diced to obtain prescribed-size modules as shown in FIG. 5.

The above-mentioned method has the following advantages:

a routine semiconductor process unit is available for the 3-inch wafer;
a use frequency of an expensive flip-chip bonder is low as a result of the embedding of passive parts;
the number of embedding steps and the cost are reduced as a result of embedding the entire wafer with resin; and
the entire wafer is evaluated for an yield ratio.

### Example 1

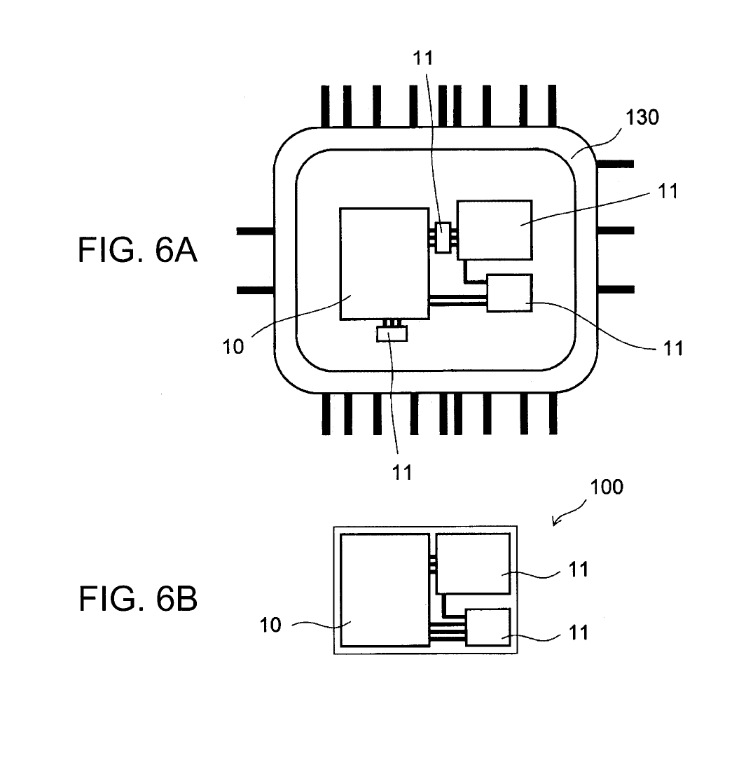

FIGS. 6A and 6B are schematic views showing a conventional X-band MMIC chip module (GaAs-FET switch) and an X-band MMIC chip module (GaAs-FET switch) of an example 1, respectively. The example 1 is smaller than the conventional one in size. The MMIC module of the example 1 is provided with a cap and input/output interconnections. Various caps of the example 1 are made of a silicon substrate having various resistivities and a glass substrate. The input/output interconnections are formed in a polyimide resin having a low dielectric constant (relative permittivity ∈ᵣ=2.9). The manufacturing process of this example has been described above.

The MMIC module of the example 1 has a high frequency chip 10 and ICs 11. The conventional module has the high frequency chip 10 and ICs 11 to be connected by wiring in the ceramic package 130. The MMIC module of the example 1 measures 4.5 mm×3.5 mm×0.5 mm. On the other hand, the conventional module typically measures 11 mm×10 mm×2 mm. It is noted that the volume of the MMIC module of the example 1 can be 1/10 or less that of the conventional module.

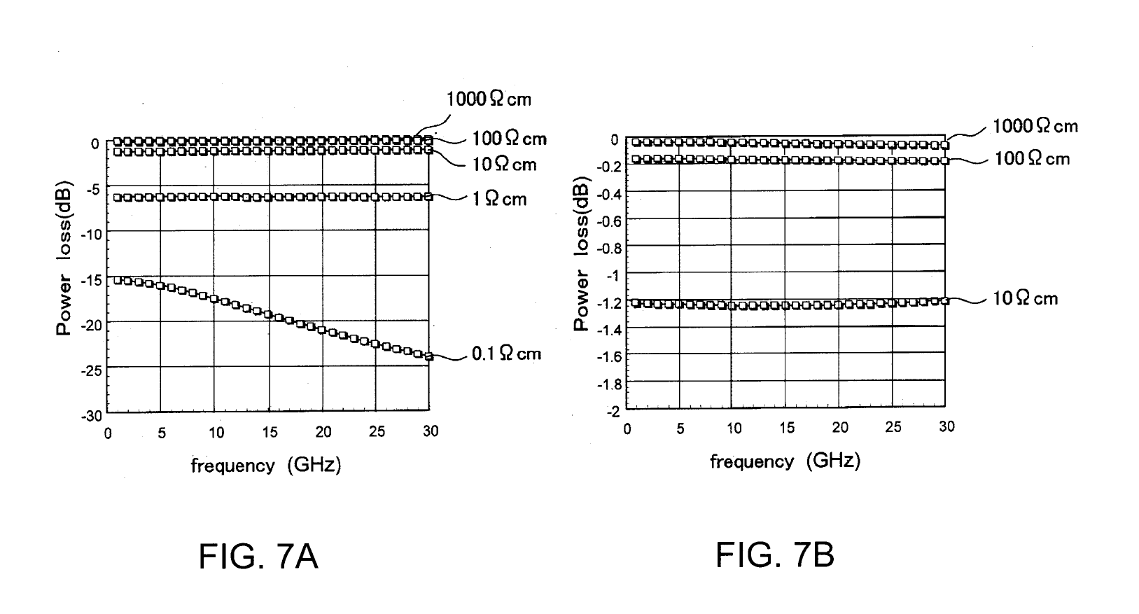

FIGS. 7A and 7B are graphs showing resistivity dependence of a power loss. The MMIC module of the example 1 was evaluated for the power loss at 100 GHz between the input/output terminals of the example 1. The resistivities are of the various caps. FIG. 7A is a view showing the power loss in the range of 30 dB or less. FIG. 7B is a view enlarging power losses of 2 dB or less which correspond to the resistivities of 10 Ωcm, 100 Ωcm, and 1000 Ωcm in FIG. 7A. FIGS. 7A and 7B show that the power loss becomes 0.5 dB or less when the resistivity is 100 Ωcm or more.

### Example 2

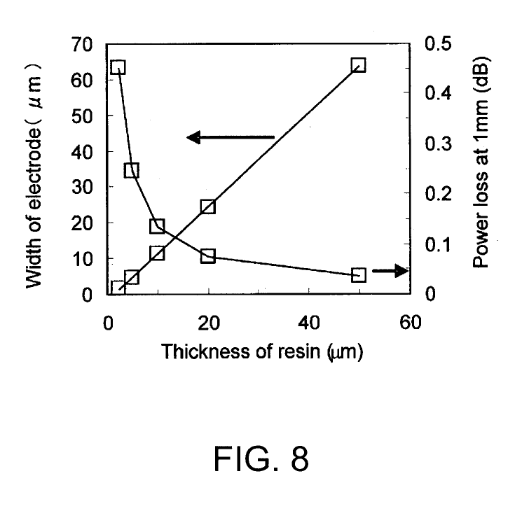

FIG. 8 is a graph showing resin-thickness dependence of an interconnection width and a power loss when setting characteristic impedance of interconnection to 50Ω. The interconnection width increases with increasing the resin thickness, while every numerical value in the graph is enabled by a routine deposition technique, routine lithography, and routine etching. The power loss decreases with increasing the interconnection width. A decrease in the power loss is due to a decrease in the resistance of a wide interconnection.

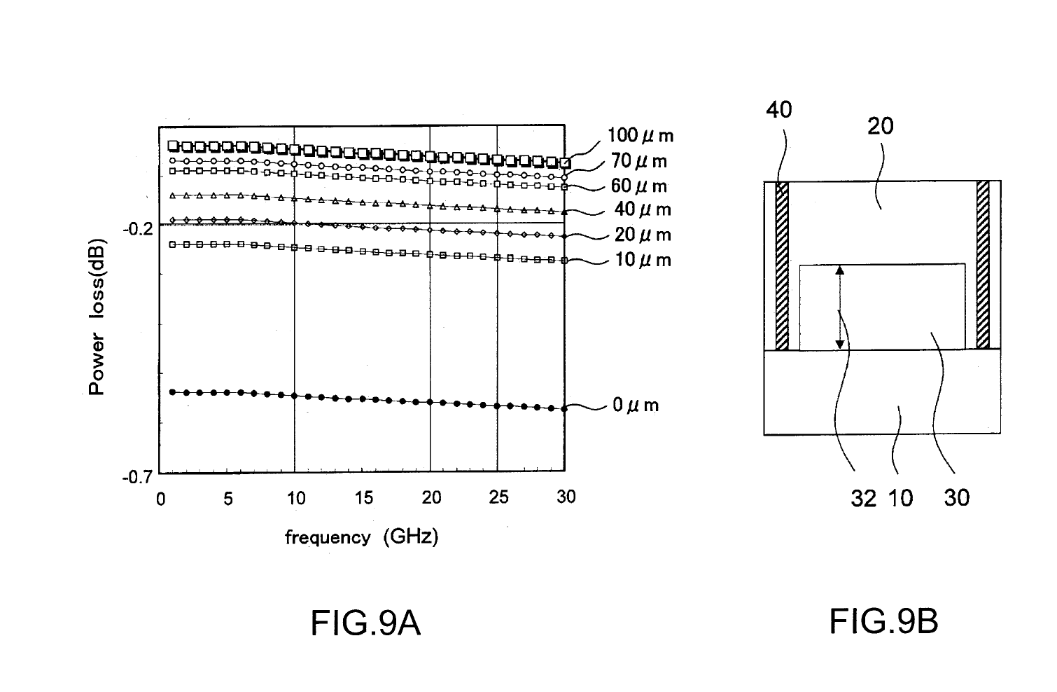

FIG. 9A is a graph showing changes in the power losses with hollow heights of 0 μm to 100 μm. FIG. 9B is a view to partially enlarge a cross section of the MMIC module. The hollow height is denoted by the double-headed arrow 32. The silicon cap 20 has a resistivity of 1000 Ωcm which is the lowest in the example 1. The interconnection thickness is 1 μm. FIG. 9A shows that the power loss is relatively large, i.e., 0.6 dB when the high frequency chip 10 is in contact with the cap 20, whereas the power loss is 0.5 dB or less when the hollow height is 10 μm or more.

### Example 3

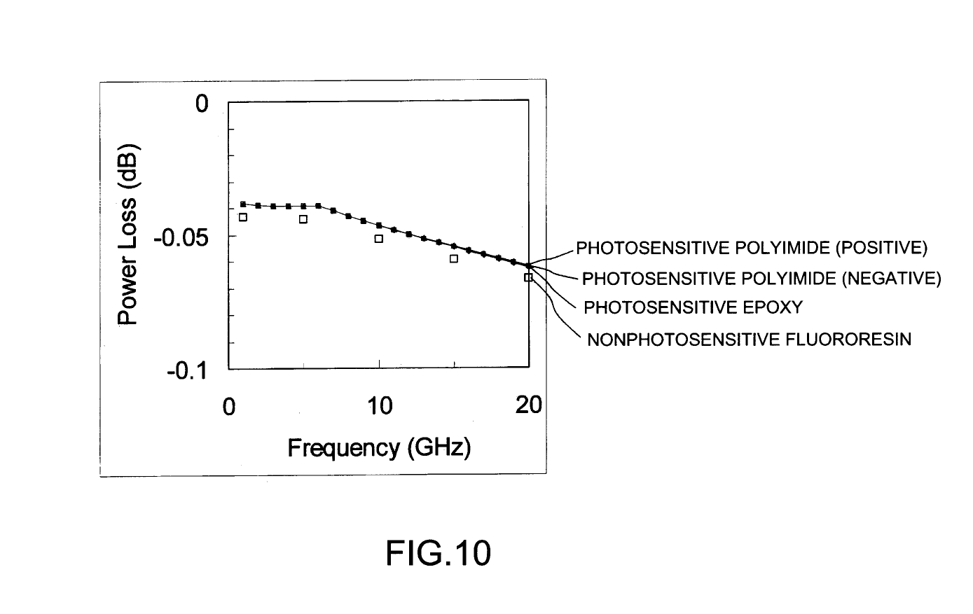

In an example 3, input/output interconnections are formed in organic resin layers having various dielectric constants. The example 3 has the same structure as that of the example 1. Physical properties of various resins are listed for comparison in Table 1. FIG. 10 is a graph showing power losses for the resin layers having various dielectric constants listed in Table 1. The power losses in the example 3 are acquired as well as in the example 1. FIG. 10 shows that the power losses do not depend on the resin layers, i.e., the dielectric constants thereof. FIG. 10 and Table 1 show that a resin layer having dielectric constants of 2 to 4 causes no problem in the manufacturing of the MMIC module.

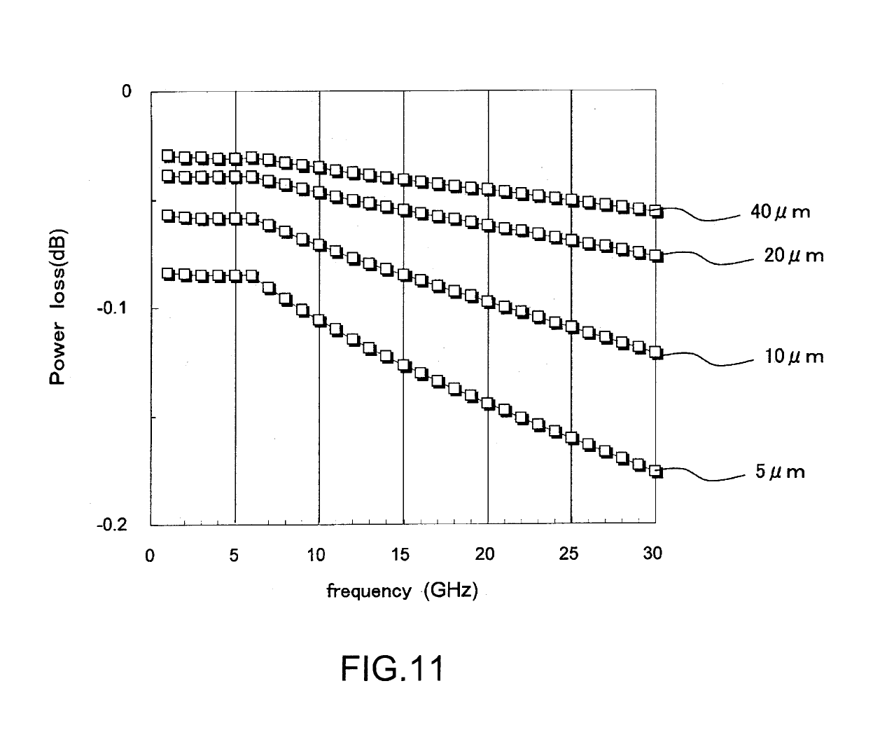

FIG. 11 is a graph showing thickness dependence of the power losses. Thicknesses of 5 μm to 40 μm are for impedance matching of the input/output interconnection. Each thickness denotes a total thickness of the third resin 3 and the fourth resin 4. The input/output interconnection includes a 1 μm-thick Au layer and is formed in the resin layer having a dielectric constant of 2.9. In order to match the input/output impedance to 50Ω, the thicknesses and widths of the third and fourth resin layer 3, 4 and the input/output interconnections 70, 71 are needed to be taken into the design of the MMIC module. When the total thickness of the third and fourth resin layers 3, 4 is decreased, the widths of the input/output interconnections decrease to increase the resistances thereof, thereby increasing the power loss. When the total thickness of the third and fourth resin layers 3, 4 is in the range of 5 μm to 40 μm, the third and fourth resin layers 3, 4 can be patterned with routine lithography. The power losses are 0.2 dB or less. Therefore, the input/output interconnections with various thicknesses and widths can be formed.

TABLE 1

| | Photo- | Photo- | | |
|---|---|---|---|---|
| | sensitive | sensitive | Photo- | Non-photo- |
| | polyimide | polyimide | sensitive | sensitive |
| | (positive) | (negative) | epoxy | fluororesin |
| Type | positive | negative | negative | non-photo |
| | | | | sensitive |
| Dielectric | 2.9 | 3.0 | 3.5 | 2.0 |
| Constant | | | | |
| (∈ᵣ) | | | | |
| Resistivity | 10¹⁵ or more | 10¹⁵ or more | 10¹⁵ or more | 10¹⁵ or more |
| (Ω cm) | | | | |
| Glass- | 230 | 220 | 300 | 350 |
| transition | | | | |
| temperature | | | | |
| (° C.) | | | | |
| Thermal | 36 | 62 | 60 | 40 |
| expansion | | | | |
| coefficient | | | | |
| (ppm/° C.) | | | | |
| 5%-weight | 480 | 380 | 450 | 500 |
| reduction | | | | |
| temperature | | | | |
| (° C.) | | | | |
| Young's | 3.9 | 3.5 | 3.0 | 3.5 |
| modulus | | | | |
| (GPa) | | | | |
| Chemical | YES | YES | YES | YES |
| tolerance (to | | | | |
| acid/alkali) | | | | |

### Example 4

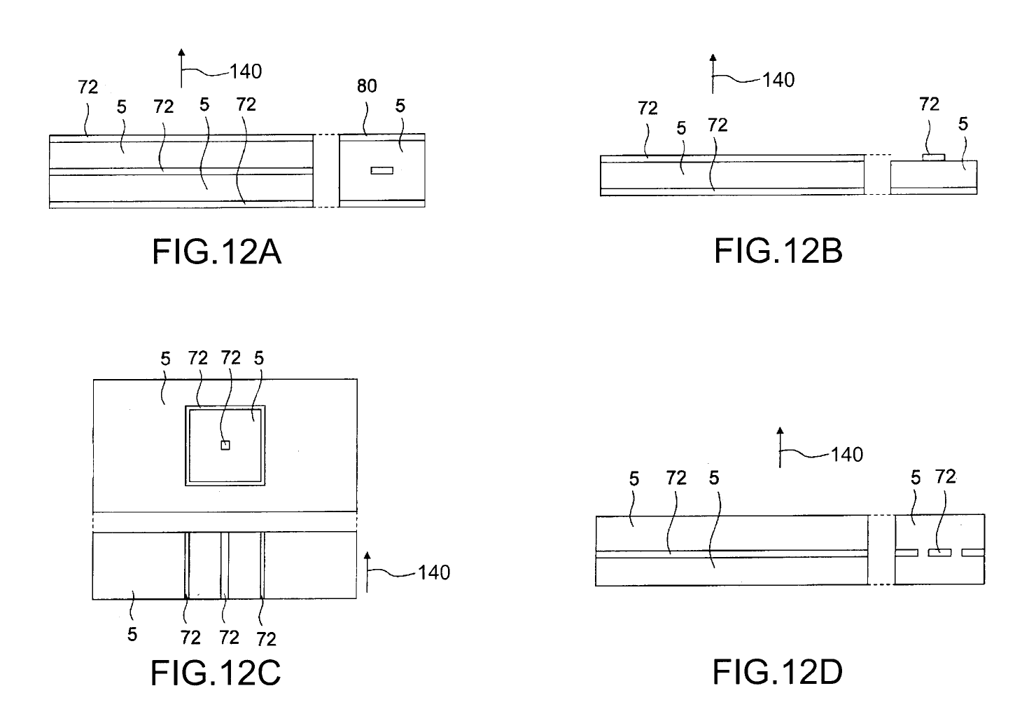

An example 4 has various forms of input/output interconnections. FIGS. 12A to 12D are plan views and top views showing forms of input/output interconnections 72 formed in the resin layer 5. FIGS. 12A, 12B, 12C, and 12D show a strip line, a micro strip line, a coaxial line, and a GSG line, respectively. In addition, a normal-line direction of the principal plane of the resin layer 5 is denoted by the arrow 140. The respective forms of the interconnections 72 are evaluated for the actual characteristic impedances and power losses. It is possible to match all the forms of interconnections to impedance of 50Ω. In addition, the measured power losses are mostly excellent, i.e., 0.1 dB.

TABLE 2

| | (a) Strip | (b) Micro | (c) Coaxial | (d) GSG |
|---|---|---|---|---|
| | line | strip line | line | line |
| Areal resistance | 0.05 | 0.06 | 0.04 | 0.05 |
| 100 μm□-capacitance | 0.12 | 0.05 | 0.15 | 0.10 |
| (pF) | | | | |
| 100 μm-indactance | 0.10 | 0.20 | 0.05 | 0.10 |
| (nH) | | | | |
| Characteristic | 50.50 | 53.50 | 50.00 | 49.50 |
| impedance (Ω) | | | | |
| Power loss at | 0.05 | 0.10 | 0.05 | 0.09 |
| 100 GHz (dB) | | | | |

In addition, a unit of Ω/□ in Table 2 denotes the unit of an areal resistance. 100 μm□ expresses a square of which side is 100 μm.

### Example 5

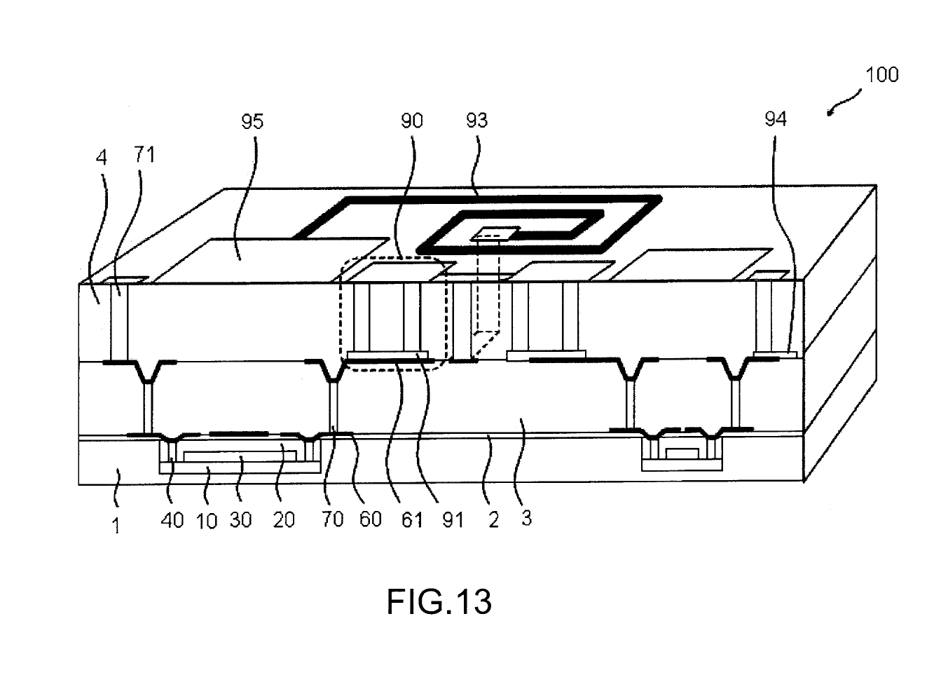

An example 5 shows a semiconductor module (MMIC module) 100 including embedded passive parts to be formed partially employing a wiring metal for a portion of input/output interconnections. FIG. 13 is a perspective view showing an example of the input/output interconnections formed with passive parts embedded. FIG. 13 shows an embedded capacitor 90, an embedded inductor (coil) 93 and an embedded register (resistance) 94. The capacitor includes a dielectric film 91. The dielectric film 91 is formed by applying a paste resin on the lead pad 80 formed on the third resin 3 and subsequently by sintering the paste resin at a low temperature. The inductor 93 is a coil formed with the material of the lead pad 80 and on the fourth resin 4. The coil is electrically in contact with the capacitor 92 via the fourth resin 4. The register 94 is a Ni system alloy layer or a conductive resin layer, which is formed on the electrode pad 61 being on the third resin 3. In addition, GND95 for grounding is formed on the fourth resin layer 4. Design values and evaluation values of the respective passive parts are listed in Table 3. Table 3 shows that the respective passive parts having the evaluation value same as the design value are formed. This result enables it to reduce the number of passive parts and to enhance the quality thereof.

TABLE 3

| | | | Additional | |
|---|---|---|---|---|
| | specification | Tolerance (%) | requirement | measured |
| Inductor | 1 to 20 Hn | 1 to 10 | High Q value | 11.5 nH |
| | | | (High | |
| | | | self-resonant | |
| | | | frequency) | |
| Capacitor | 1 to 20 Hn | 1 to 10 | High Q value | 5.1 pF |
| | | | (High | |
| | | | self-resonant | |
| | | | frequency) | |
| Decoupling | 0.01 to 0.1 μF | 10 to 20 | Low | 0.02 μF |
| capacitor | | | resistance in | |
| | | | series | |
| Terminal | 20 to 100 Ω | 1 to 10 | | 50.5 Ω |
| resistance | | | | |
| Circuit | 10 to 100 Ω | 1 to 10 | High | 80 Ω |
| resistance | | | accuracy | |

In addition to the above examples, materials of insulating caps, plating materials, sealing resins, resins on which input/output interconnections are formed, and materials of input/output interconnections are to be selected. Furthermore, a multilayer having a different structure, conductive resins, and a functionally gradient material may be employed to form a semiconductor module. Selecting various conducting films allows it to fabricate the conducting films using a damascene process. The present invention can be reduced to practice, i.e., fields of various semiconductor devices, such as a logic device, a memory device, a power device, an optical device, a MEMS device, a sensor device and so on.

As described above, this embodiment enables it to reduce the power loss of a semiconductor module. This embodiment also enables a remarkable miniaturization, price reductions, and accelerating product development for the described high-frequency modules without sacrificing electric properties of the modules. In addition to these results, an external matching circuit is not necessary, thereby enabling it to further reduce the whole number of mounted parts and to lead to further price reductions. The embodiment enables it not only to manufacture the above-mentioned semiconductor module with a routine semiconductor process system but also to evaluate a yield ratio of the modules in a wafer form. This also leads to acceleration of 100% evaluation of products, thereby reducing defective products remarkably. As described above, the invention is not limited to the filed of high frequency modules, but can be reduced to practice in fields of power semiconductor modules, MEMS modules, sensor modules and so on, thereby contributing to multiple functions of electronic devices.

As described above, the embodiments have been explained with reference to several examples. However, the invention is not limited to these specific examples

While a certain embodiment of the invention has been described, the embodiment has been presented by way of examples only, and is not intended to limit the scope of the inventions. Indeed, the novel elements and apparatuses described herein may be embodied in a variety of other forms; furthermore, various omissions, substitutions and changes in the form of the methods described herein may be made without departing from the spirit of the invention. The accompanying claims and their equivalents are intended to cover such forms or modifications as would fall within the scope and spirit of the invention.

What is claimed is:

1. A semiconductor module comprising:
a high frequency chip;
an insulating cap forming a hollow with the chip to cover the chip;
a through electrode passing through a first plane of the cap and a second plane of the plane, the first plane facing the chip, the second plane being on a side opposite to the first plane;
interconnections being provided on the cap and connected to the through electrode; and
an insulating layer being provided on the cap and filling a portion between the interconnections therewith.

2. The module according to claim 1, wherein the cap includes at least one selected from the group consisting of insulator glass and high-resistance silicon.

3. The module according to claim 2, wherein at least a portion of the insulating layer includes an organic resin.

4. The module according to claim 3, wherein the interconnections include at least one line selected from the group consisting of a strip line, a micro strip line, a coplanar line, and a coaxial line.

5. The module according to claim 4, wherein a portion of the interconnections and a portion of the insulating layer form at least one selected from the group consisting of a capacitor, an inductor, and a resistor.

6. The module according to claim 5, wherein the hollow measures 10 μm or more height.

7. A manufacturing method of a semiconductor module, comprising:
forming a through electrode in a trench of an insulating wafer having the trench and a through hole;
making a high frequency chip and the wafer face each other via the trench;
arranging the chip in a first resin;
forming a second resin on the wafer; and
forming interconnections in the second resin, the interconnections being connected to the through electrode.

8. A manufacturing method of a semiconductor module, comprising:
forming a through electrode in a trench of an insulating wafer having the trench and a through hole, the trench measuring 10 μm or more height;
making a high frequency chip and the wafer face each other via the trench;
arranging the chip in a first resin;
forming a second resin on the wafer; and
forming interconnections in the second resin, the interconnections being connected to the through electrode.
